(19) United States
(12) Patent Application Publication
(10) Pub. No.: US 2008/0093632 A1
(43) Pub. Date: Apr. 24, 2008

(54) Size-reduced layout of cell-based integrated circuit with power switch

(75) Inventor: Taro Sakurabayashi, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 11/907,977

(22) Filed: Oct. 19, 2007

(30) Foreign Application Priority Data
Oct. 19, 2006 (JP) 2006-285404

(51) Int. Cl. H01L 23/528

(52) U.S. Cl. 257/207; 257/E23.153

(57) ABSTRACT

An integrated circuit is provided with a first power line, a plurality of additional power lines intersecting with the first power line, a plurality of power switch transistors each having a drain connected with the first power line and a source connected with one of the additional power lines, a well provided to extend along the first power line; and a plurality of primitive cells each including a first transistor prepared within the well, the first transistor having a source connected with the first power line. The plurality of additional power lines includes first and second additional power lines The plurality of primitive cells are provided between the first and second additional power lines along the first power line. A bias voltage is fed to the well through both of first and second well contacts, the first well contact providing a connection between the first additional power line and the well, and the second well contact providing a connection between the second additional power line and the well.

This application claims the benefit of priority based on Japanese Patent Application No. 2006-285404, filed on Oct. 19, 2006, the disclosure of which is incorporated herein by reference.

### BACKGROUND OF THE INVENTION

1. Field of the invention

The present invention relates to a semiconductor integrated circuit, more particularly, to a cell-based integrated circuit with power switches that control the power supply to primitive cells.

2. Description of the Related Art

The increase in the leak current is one of the major issues in device dimension reduction of semiconductor integrated circuits. This also applies to cell-based integrated circuits. When a cell-based integrated circuit is placed into standby mode, the power consumption is desirably reduced as low as possible; however leak currents through deactivated primitive cells often account for a major part of the total power consumption. One approach for addressing this problem is to stop the power supply to the deactivated primitive cells; this effectively reduces the leak currents in standby.

FIG. 11 is a layout diagram of a conventional cell-based integrated circuit disclosed in Japanese Laid-Open Patent Application No. JP-P2004-186666A, in which the power supply to primitive cells is controlled by power switches. The disclosed cell-based integrated circuit is provided with primitive cells 50 and a power switch cell 60. The primitive cells 50 are designed with CMOS (Complementary Metal Oxide Semiconductor) architecture. The power switch cell 60 controls the power supply to the primitive cells 50. The power switch cells 60 each include a P-channel type transistor 54 which supplies the power source voltage received from a VDD power line 70 to a VSD power line 71. The power source voltage on the VDD power line 70 may be different from that on the VSD power line 71, because the power supply to the VSD power line 71 may be stopped in the standby mode. Therefore, the power source voltage generated on the VDD power line 70 is referred to as the power source voltage VDD, while the power source voltage supplied to the VSD power line 71 is referred to as the virtual power source voltage VSD. The primitive cells 50 are designed with CMOS architecture. In FIG. 11, each primitive cell 50 includes a PMOS transistor 51 and an NMOS transistor 52.

The PMOS transistors 51 and 54 are commonly provided within an N-well 41, and the power source voltage VDD is supplied from the VDD power line 70 to the N-well 41 as the substrate bias (or the backgate bias) of the PMOS transistors 51 and 54.

A description is given of details of the layout of the conventional cell-based integrated circuit in the following. The PMOS transistors 51 are each provided with by P-type diffusion layers 43 and 44 and a gate 45, the P-type diffusion layers 43 and 44 being provided within the N-well 41. The power source voltage VDD is supplied to the N-well 41 thorough well contacts 65 which are formed as N-type diffusion layers within the N-well 41. The well contacts 65 are provided in the respective primitive cells 50. It should be noted that the configuration is schematically illustrated in FIG. 11 for easy understanding; although the well contacts 65 are shown as being out of alignment from the VDD power line 70, the well contacts 65 are actually formed just under the VDD power line 70 and the VDD power line 70 is connected with the N-well 41 through the well contacts 65. The virtual power source voltage VSD is supplied to the P-type diffusion layers 43, which functions as sources of the PMOS transistors 51, through contacts (not shown) from the VSD power line 71. The NMOS transistors 52 are each provided with an N-type diffusion layers 46 and 47 and a gate 49, which are provided for a P-well 42. The ground voltage GND is supplied to the P-well 42 via well contacts 48 as the substrate bias (or the backgate bias) of the NMOS transistors 52. The well contacts 48, which are formed as the P-type diffusion layers, are provided within the respective primitive cells 50. The ground voltage GND is also supplied to the N-type diffusion layers 46, which function as sources of the NMOS transistors 52, through contacts (not shown) from a ground line 72. The PMOS transistor 54 is provided with of P-type diffusion layers 62, 63 and a gate 64, the P-type diffusion layers 62 and 63 being provided within the N-well 41. The P-type diffusion layers 62 and 63 may be referred to as the source region 62 and the drain region 63, respectively, hereinafter. Prepared beside the PMOS transistor 54 within the power switch cell 60 is a well contact 61 that supply the power source voltage VDD to the N-well 41 as the substrate bias (or the backgate bias) of the PMOS transistor 54. The source region 62 of the PMOS transistor 54 is connected to the VDD power line 70 and the drain region 63 is connected to the VSD power line 71; the PMOS transistor 54 works as a power switch transistor. When the power transistor (or the PMOS transistor 54) is turned on, the virtual power source voltage VSD is supplied to the VSD power line 71 from the drain region 63. When the power transistor is turned off, on the other hand, the VSD power line 71 is electrically separated from the VDD power line 70; the power source voltage is not supplied to suppress the leak current.

One drawback of the conventional integrated circuit shown in FIG. 11 is the increased circuit size. Since the well contacts 65 are provided in the respective primitive cells 50, the layout of the conventional integrated circuit requires extending the VDD power line 70 along the array of the primitive cells 50 for supplying the power source voltage VDD to the N-well 41, in addition to the VSD power line 71 which supplies the virtual power source voltage VSD to the sources of the PMOS transistors 51 within the primitive cell 50. The VDD power line 70 and the VSD power line 71 are inevitably prepared in the same interconnection layer (typically, the lowest interconnection layer), because the VDD power line 70 and the VSD power line 71 provides the power source voltages VDD and VSD for the well contacts 65 and the P-type diffusion layers 43, respectively, within the respective primitive cells 50. Accordingly, the VDD power line 70 and the VSD power line 71 must be spaced from each other with a certain separation, which is indicated by the symbol “a” in FIG. 11). The size of the conventional integrated circuit shown in FIG. 11 is undesirably increased; the distance between the VDD power line 70 and the ground line 72 is increased for providing the separation “a” of the VDD power line 70 and the VSD power line 71, in addition to the cell height “b” of the primitive cells 50.

Japanese Laid Open Patent Application No. JP-A-Heisei, 11-150193 also discloses a CMOS integrated circuit provided with a virtual power line and a PMOS power switch that controls the power supply to the virtual power line. In this CMOS integrated circuit, an N-well is shared by the PMOS power switch and PMOS transistors within primitive cells, and a well contact used to feed the power supply voltage is prepared out of the primitive cells. Japanese Laid-Open Patent Application No. JP-P2001-196545A discloses a similar technique.

### SUMMARY

In an embodiment of the present invention, an integrated circuit is provided with a first power line, a plurality of additional power lines intersecting with the first power line, a plurality of power switch transistors each having a drain connected with the first power line and a source connected with one of the additional power lines, a well provided to extend along the first power line; and a plurality of primitive cells each including a first transistor prepared within the well, the first transistor having a source connected with the first power line. The plurality of additional power lines includes first and second additional power lines The plurality of primitive cells are provided between the first and second additional power lines along the first power line. A bias voltage is fed to the well through both of first and second well contacts, the first well contact providing a connection between the first additional power line and the well, and the second well contact providing a connection between the second additional power line and the well.

The present invention effectively reduces the circuit size of cell-based integrated circuits in which power switch cells are provided to control the power supply for the suppression of the leak current through cells in the non-operating state.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a plain view illustrating an integrated circuit in a first embodiment of the present invention;

FIG. 2 is a circuit diagram of a primitive cell and a power switch cell in the first embodiment;

FIG. 3 is a plain view showing an exemplary layout and element connections of the functional cell in the first embodiment;

FIG. 4 is a plain view showing an exemplary layout of element regions of the functional cell in the first embodiment according to the present invention;

FIG. 5 is a plain view showing an exemplary layout and element connections of the functional cell in a variant of the first embodiment;

FIGS. 6A and 6B are plain views showing other exemplary arrangement examples of well contacts to an N-well and a power switch cells in the first embodiment;

FIG. 7 is a plain view of an integrated circuit of a second embodiment of the present invention;

FIG. 8 is a circuit diagram of a primitive cell and a power switch cell in the second embodiment;

FIG. 9 is a plain view showing an exemplary layout and element connections of the functional cell in the second embodiment;

FIGS. 10A and 10B are plain views showing other exemplary arrangements of well contacts to an N-well and a power switch cell in the second embodiment;

FIG. 11 is a plain view showing the layout and element connections of a functional cell in an connectional cell-based integrated circuit; and

FIG. 12 is a plain view showing the layout and element connections of a functional cell in a prototype integrated circuit.

### DESCRIPTION OF PREFERRED EMBODIMENTS

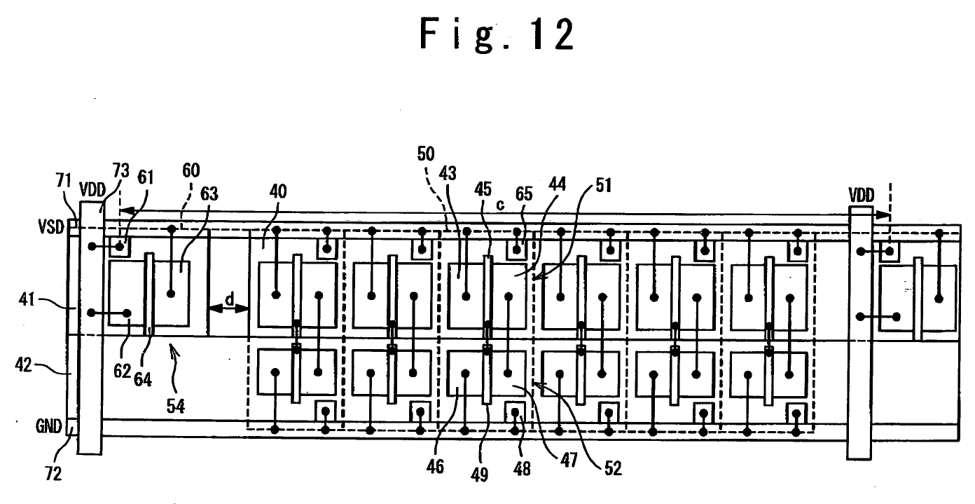

Before describing of the present invention, a prototype of the integrated circuit of the present invention will be explained in detail with reference to FIG. 12 in order to facilitate the understanding of the present invention.

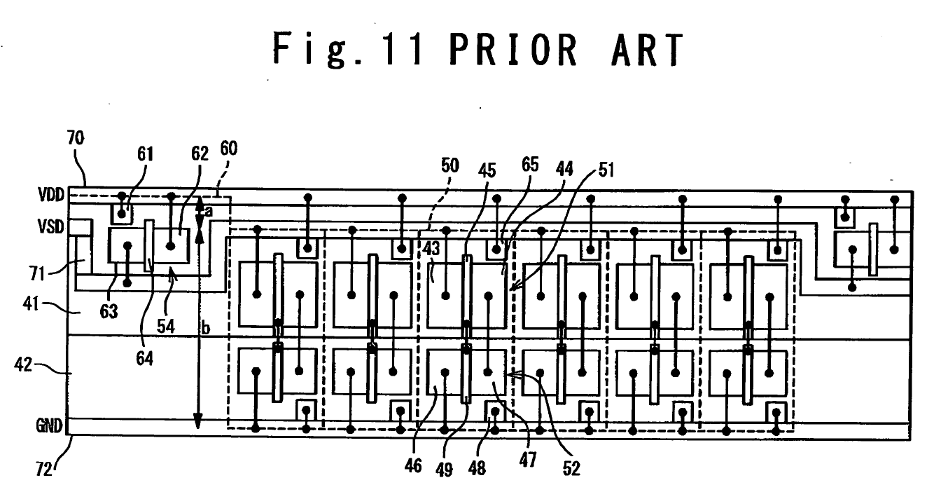

FIG. 12 is a layout diagram of the prototype integrated circuit. It should be noted that same reference numerals denote same elements as those of FIG. 11. In the integrated circuit shown in FIG. 12, a PMOS transistor 54 in a power switch cell 60 is provided within an N-well 41, and the PMOS transistors 51 in the primitive cells 50 are provided within a different N-well 40. The power source voltage VDD is supplied to the N-well 41 from the VDD power line 71 to develop the substrate potential of the PMOS transistor 54, and the virtual power source voltage VSD is supplied to the N-well 40 from the VSD power line 71 to develop the substrate potential of the PMOS transistor 51.

The layout shown in FIG. 12 allows the VDD power line 73 to be formed in an interconnection layer located over the interconnection layer in which the VSD power line 71 is located, for the supply of the power source voltage VDD to the well contact 61. As a result, the layout shown in FIG. 12 eliminates the need of providing an increased circuit area for the separation of the VDD power line 73 and the VSD power line 71.

Although eliminating the need for extending the VDD poser source line 73 along the respective primitive cells 50, the layout shown in FIG. 12 requires a region for the separation between the N-wells 40 and 41 as indicated by the symbol “d”, since the N-wells 40 and 41 have different potential levels. There is a room for further reducing the circuit size in the layout of FIG. 12.

The present invention effectively addresses the above-mentioned problems. The present invention will be now described herein with reference to illustrative embodiments. Those skilled in the art will recognize that many alternative embodiments can be accomplished using the teachings of the present invention and that the invention is not limited to the embodiments illustrated for explanatory purposes. In the following, a description is given of an integrated circuit 200 including a functional cell 100 in which the power supply is controlled in response to the switching between normal and standby modes. It should be noted that the normal mode is a status in which normal operations are executed and the standby mode is a status in which the operations of some of the functional cells are suspended.

### First Embodiment

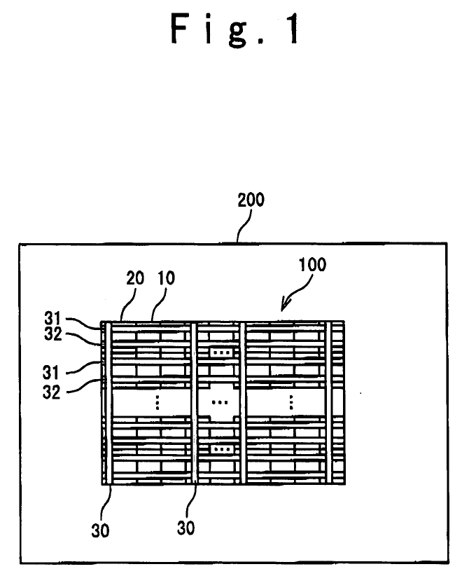

Referring to FIG. 1 to 6, an integrated circuit 200 of a first embodiment of the present embodiment will be described in the following. FIG. 1 is a plain view of the integrated circuit 200 in the first embodiment. The integrated circuit 200 includes a functional cell 100. The functional cell 100 includes primitive cells 10, power switch cells 20, VDD power lines 30, VSD power lines 31, and ground lines 32. VDD power lines 30 intersect with the VSD power lines 31 and the ground lines 32. The primitive cells 10 are arranged in rows and columns in the functional cell 100. The primitive cells 10 each include a logic circuit designed with CMOS architecture. The power switch cells 20 control the power supply to the primitive cells 10 within the function cell 100. The logic circuits within the primitive cells 10 operate on the power source voltage and the ground voltage supplied from the VSD power lines 31 and the ground lines 32, respectively. The power switch cells 20 supply the power source voltage received from the VDD power lines 30 to the VSD power lines 31. In order to distinguish the power source voltages generated on the VDD power lines 30 and the VSD power lines 31, the power source voltage generated on the VDD power lines 30 is referred to as the power source voltage VDD, hereinafter, while the power source voltage generated on the VSD power lines 31 is referred to as the virtual power source voltage VSD, hereinafter.

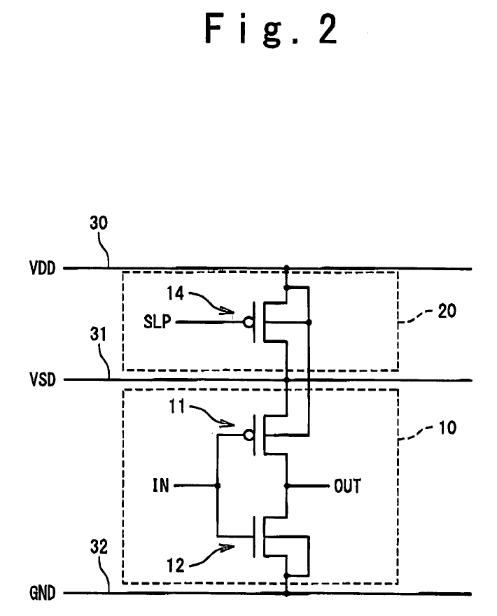

FIG. 2 is a circuit diagram illustrating an exemplary configuration of the primitive cells 10 and the power switch cells 20 in the first embodiment. The primitive cells 10 each include a PMOS transistor 11 having a source connected with the VSD power line 31 and an NMOS transistor 12 having a source connected with the ground line 32. The PMOS and NMOS transistors 11 and 12 are connected with each other to function as a CMOS device, outputting an output signal OUT in response to an input signal IN. Although shown as including a CMOS inverter in FIG. 2, the primitive cells 10 may include other kinds of CMOS circuits. The substrate node (or the backgate) of the PMOS transistor 11 is biased with the power source voltage VDD received from the VDD power line 30, and the substrate node (or the backgate) of the NMOS transistor 12 is biased with the ground voltage GND received from the ground line 32.

The power switch cells 20 each include a PMOS transistor 14 connected between the VDD power line 30 and the VSD power line 31. The PMOS transistor 14 controls the supply of the virtual power source voltage VSD in response to a switch control signal SLP fed to the gate thereof; the PMOS transistor 14 works as a power switch transistor. When the PMOS transistor 14 is turned on in response to the assertion of the switch control signal SLP, the virtual power source voltage VSD is generated on the VSD power line 31 to have the same level as the power source voltage VDD received from the VDD power line 30. When the PMOS transistor 14 is turned off, on the other hand, the VSD power line 31 is disconnected from the VDD power line 30. The power source voltage VDD is supplied to the substrate node (or the backgate) of the PMOS transistor 14 from the VDD power line 30. Although FIG. 2 shows a configuration in which only one primitive cell 10 is prepared for one power switch cell 20, it would be understood that multiple power switch cells 20 may be connected with multiple primitive cells 10.

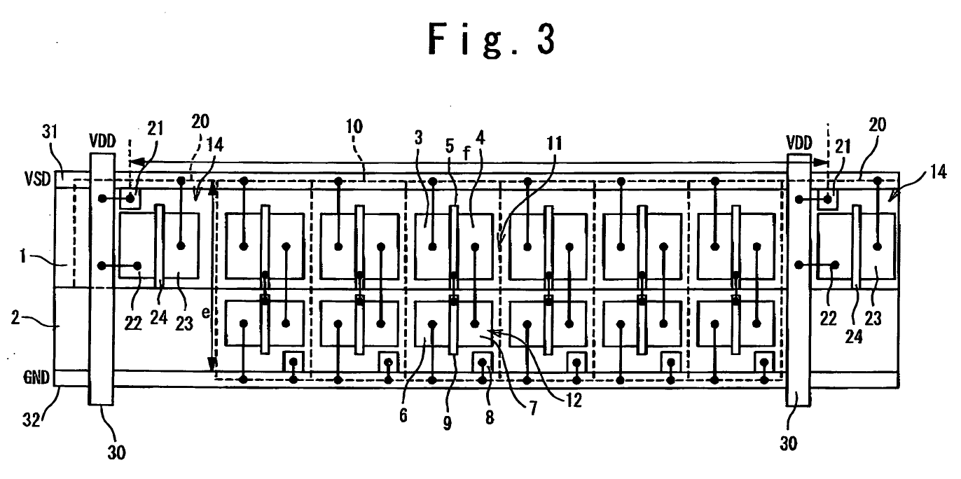

FIG. 3 is a plain view showing an exemplary layout of the functional cell 100 and connections of elements within the functional cell 100. The PMOS transistors 11 of the primitive cells 10 are provided within an N-well 1, while the NMOS transistors 12 are provided within a P-well 2. The PMOS transistors 11 are each composed of P-type diffusion layers 3, 4 and a gate 5, the P-type diffusion layers 3 and 4 being formed within the N-well 1. The NMOS transistors 12 are each composed of N-type diffusion layers 6, 7 and a gate 9, the N-type diffusion layers 6 and 7 being provided within the P-well 2. The PMOS transistors 14 within the power switch cells 20 are also prepared within the N-well 1, commonly with the PMOS transistors 11.

From the inventor's study, well contacts for supplying the substrate bias (or the backgate bias) to the N-well 1 do not have to be provided within the primitive cells 10 for the case that the latch-up is surely avoided by any technique, because no large electric current flows through the N-well 1 in general. In this embodiment, well contacts that supply the substrate bias (or the backgate bias) of the PMOS transistors 11 are provided within the N-well 1 outside the primitive cells 10. In this embodiment, the well contacts are formed as N-type diffusion layers 21 within the power switch cells 20. The N-type diffusion layers 21 are provided in the power switch cell 20 as a well contact for the N-well 1. The N-type diffusion layers 21 are connected to the VDD power lines 30, and the power source voltage VDD is supplied to the respective N-type diffusion layers 21; the power source voltage VDD is supplied through the N-type diffusion layers 21 to the N-well 1 as the substrate bias for both of the PMOS transistors 11 and 14.

The substrate bias (or the backgate bias) of the NMOS transistors 12 is supplied to the P-well 2 through P-type diffusion layers 8 provided within the primitive cells 10, the P-type diffusion layers 8 functioning as well contacts. The P-type diffusion layers B are connected to the ground line 32. The ground voltage GND is supplied to the P-well 2 as the substrate bias, within each primitive cell 10.

The PMOS transistors 14 within the power switch cells 20 are each provided with P-type diffusion layers 22 and 23, and a gate 24. The P-type diffusion layers 22, which function as source regions, are connected with the VDD power lines 30 through via-contacts (not shown in FIG. 3), and the power source voltage VDD is supplied to the P-type diffusion layers 22. The P-type diffusion layers 23, which function as drain regions, are connected with the VSD power lines 31 through via-contacts (not shown in FIG. 3). The virtual power potential VSD is supplied to the VSD power lines 31 from the P-type diffusion layers 23. It should be noted that the configuration of the functional cell 100 is schematically illustrated in FIG. 3 for easy understanding. Although the VDD power lines 30 are shown in FIG. 3 as being separated from the P-type diffusion layers 22 in the in-plane direction, the P-type diffusion layers 22 may be positioned just under the VDD power lines 30 and connected with the VDD power line 30 through via-contacts.

The P-type diffusion layer 3, which function as the source regions of the PMOS transistors 11, are connected with the VSD power lines 31 through via-contacts (not shown in FIG. 3), and the virtual power source voltage VSD is supplied to the P-type diffusion layers 3. The N-type diffusion layers 6, which function as the source regions of NMOS transistors 12, are connected with the ground lines 32 through via-contacts (not shown in FIG. 3), and the ground voltage GND is supplied to the N-type diffusion layers 6. The gates 5 of the PMOS transistors 11 are connected with the gates 9 of the NMOS transistors 12, respectively, and the P-type diffusion layers 4 (the drain regions) of the PMOS transistors 11 are connected with the N-type diffusion layers 7 (the drain region) of the NMOS transistors 12, respectively.

The N-type diffusion layers 21 within the power switch cells 20 are provided at constant intervals, and a plurality of the primitive cells 10 are arrayed along the VSD power line 31 between adjacent two of the N-type diffusion layers 21. The N-type diffusion layers 21, which function as the well contacts, are arranged so that the substrate bias is stably fixed over the array of the primitive cells 10. When a specific primitive cell 10 is positioned too far from the nearest N-type diffusion layer 21, the substrate bias fed to the specific primitive cell 10 may be lowered from the power source voltage VDD due to the voltage drop across the N-well 1. Therefore, the N-type diffusion layers 21 and the primitive cells 10 are arranged so that each primitive cell 10 is positioned within an appropriate distance from the nearest N-type diffusion layer 21; this allows stably fixing the substrate bias so that the PMOS transistors 11 surely have desired threshold voltages. The number of the primitive cells 10 provided between adjacent two of the N-type diffusion layers 21 (that is, the distance “f” between adjacent two N-type diffusion layers 21) is determined so that each primitive cell 10 is positioned within an appropriate distance from the nearest N-type diffusion layer 21.

Similarly, the power switch cells 20 are positioned so that the source bias of the PMOS transistors 11 is firmly fixed to the level of the virtual power source voltage VSD over the array of the primitive cells 10. When a specific primitive cell 10 is positioned too far from the nearest power switch cell 20, the source bias fed to the certain primitive cell 10 may be lowered from the original level of the virtual power source voltage VSD due to the voltage drop across the VSD power line 31. Therefore, the power switch cells 20 and the primitive cells 10 are arranged so that each primitive cell 10 is positioned within an appropriate distance from the nearest power switch cell 20; this allows stably fixing the source bias so that the PMOS transistors 11 surely have desired threshold voltages. The number of the primitive cells 10 provided between adjacent two of the power switch cells 20 (that is, the distance between adjacent two power switch cells 20) is determined so that each primitive cell 10 is positioned with an appropriate distance from the nearest power switch cell 20.

In this embodiment, the distance between adjacent two of the power switch cells 20 (that is, the distance “f” between adjacent two of the N type diffusion layers 21) is determined in consideration of the levels of the supplied substrate bias (desirably identical to the power source voltage VDD) and the supplied source bias (desirably identical to the virtual power potential VSD), since the N-type diffusion layers 21 are provided within the power switch cells 20. Generally, the substrate bias with a sufficient bias level can be supplied to the respective PMOS transistors 11, when the power switch cells 20 are separated with a distance determined in consideration of the bias level of the source bias fed to the P-type diffusion layers 3.

The VSD power lines 31 and the ground lines 32 are both provided in the first interconnection layer (the lowest interconnection layer), extending in parallel to each other in a certain direction (referred to as the horizontal direction, hereinafter). The VDD power lines 30 are provided in an upper interconnection layer positioned over the first (lowest) interconnection layer, extending along the column of the power switch cells 20 in a direction perpendicular to the horizontal direction (referred to as the vertical direction, hereinafter). The VDD power lines 30 are connected with the N-type diffusion layers 21 and the P-type diffusion layers 22 of the PMOS transistors 14. In the first embodiment, the VDD power lines 30 are not required to be positioned in the first (lowest) interconnection layer, since the power source voltage VDD is not supplied to each primitive cell 10, differently from the conventional integrated circuit shown in FIG. 11. Therefore, the integrated circuit of this embodiment does not require providing the separation “a” for separating the VDD power lines from the VSD power line, differently from the conventional integrated circuit shown in FIG. 11; the circuit size of the integrated circuit of this embodiment depends on the cell height “e” of the primitive cells 10. Therefore, the layout of the integrated circuit in this embodiment effectively reduces the circuit size in comparison with the conventional technique.

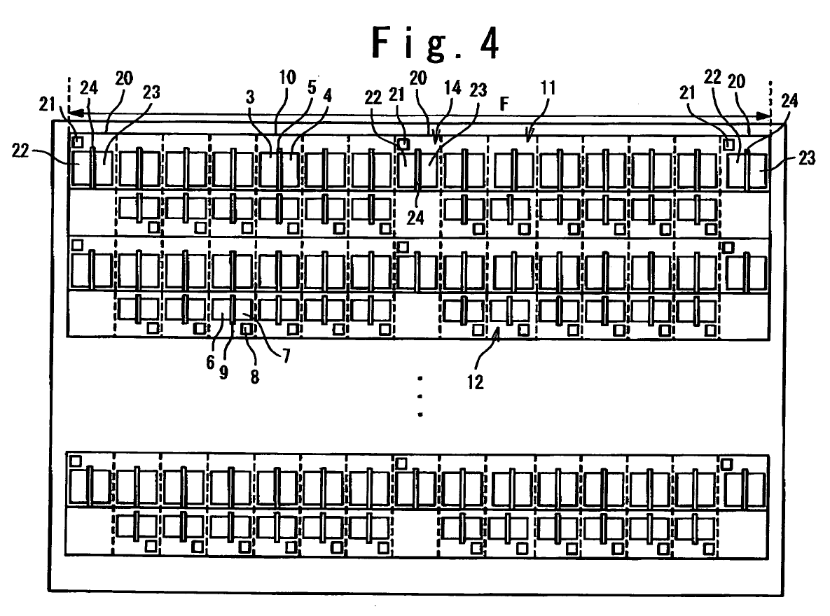

FIG. 4 is a plain view showing a preferred layout of the element regions within the functional cell 100 in the first embodiment. For easy understanding of the connections within the functional cell 100, FIG. 3 shows a layout in which the VDD power lines 30, the VSD power lines 31, and the ground lines 32 are shifted from the N-type diffusion layers 21, the P-type diffusion layers 22 and the P-type diffusion layers 8 in the in-plane direction; however, such layout is impractical, because of the increased circuit size. In an actual implementation, the VDD power lines 30, the VSD power lines 31, and the ground lines 32 are positioned to overlap the N-type diffusion layers 21, the P-type diffusion layers 22 and the P-type diffusion layers B. FIG. 4 illustrates a more practical layout of element regions (that is, wells and diffusion layers) of the functional cell 100. As shown in FIG. 4, multiple columns of the primitive cells 10 are located between adjacent columns of the power switch cells 20 in the functional cell 100. A PMOS transistor 14 of a specific power switch cell 20 is provided with the same N-well 1 as the PMOS transistors 11 of the corresponding primitive cells 10; the substrate bias of the PMOS transistor 14 of the specific power switch cell 20 is identical to that of the PMOS transistors 11 of the corresponding primitive cells 10. Therefore, the element isolation (denoted by the symbol “d” in FIG. 12) is not required between the power switch cells 20 and the primitive cells 10. Therefore, the circuit dimension F of the functional cell 100 in this embodiment is smaller than the circuit dimension C of the functional cell shown in FIG. 12.

Although all the primitive cells 10 are arranged in the same direction in the layout shown in FIG. 4, one ground line 32 is shared by adjacent rows of the primitive cells 10, and the primitive cells 10 in the adjacent rows may be arranged in a mirror symmetric with respect to the ground line 31. This effectively reduces the circuit size. Correspondingly, one VSD poser line 31 may be shared by adjacent rows of the primitive cells 10, when the supply of the virtual power voltage VSD to the adjacent rows of the primitive cells 10 are started and stopped at the same time.

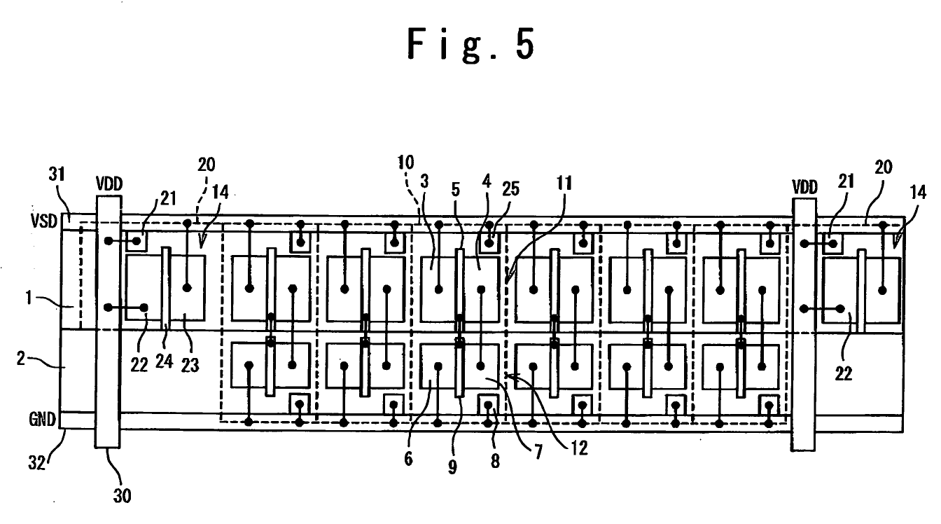

FIG. 5 is a variant of the first embodiment of the present invention. The configuration of FIG. 5 addresses supplying the virtual power source voltage VDS to the N-well 1 through the P-type diffusion layers 25 within the respective primitive cells 10. The P-type diffusion layers 25 functions as well contacts to the N-well 1. It should be noted that the P-type diffusion layers 25, instead of N-type diffusion layer, are used to achieve electrical connections with the N-well 1. Generally, primitive cells which are not adapted to the power supply through power switches are designed to include N-type diffusion layers functioning well contacts to an N-well, because the source and substrate biases are commonly fed from a VDD power line, as is the case of the configuration shown in FIG. 11. Such-designed primitive cells, however, undesirably cause short-circuit between the VDD and VSD power source lines 30 and 31 when used in the function cell 100. The configuration of the variant shown in FIG. 5 is what the N-type diffusion layers within primitive cells that are not adapted to power switch are replaced with the P-type diffusion layers 25. Such replacement allows primitive cells that are not adapted to power supply control using power switches to be adapted thereto with simple modification.

Further, when the P type diffusion layers 25 are adjacent to the source regions 3 of the PMOS transistors 11, the P type diffusion layers 25 may be used as source contacts of the PMOS transistors 11.

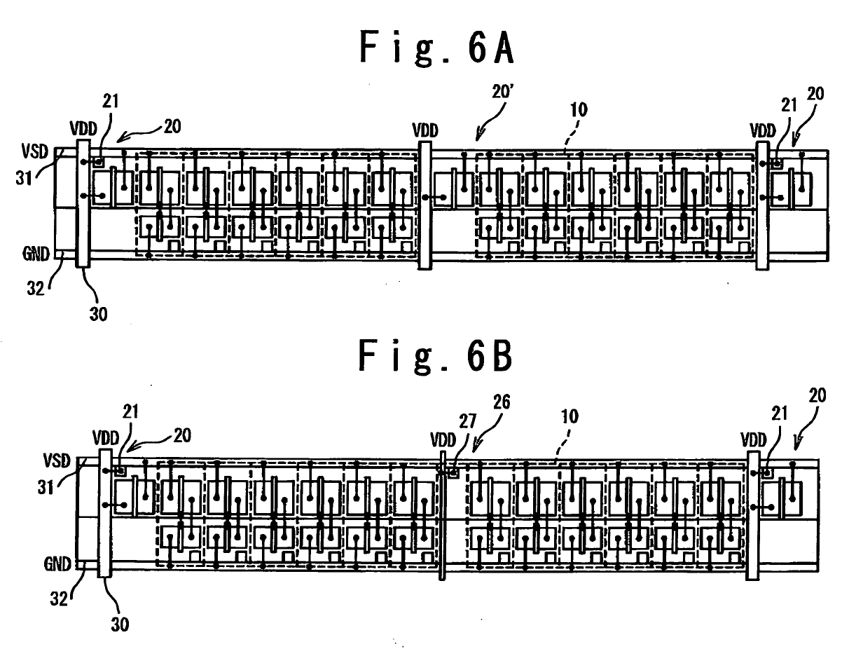

FIGS. 6A and 6B are other exemplary arrangements of the power switch cells 20 and the N-type diffusion layers 21, which are the well contacts to the N-well 1. The numbers of N-type diffusion layers 21 and the power switch cell 20 may be arbitrary modified depending on the drive capacities of the PMOS transistors 11 and 14; the N-type diffusion layers 21 and the power switch cell 20 may not be in one-to-one correspondence to each other as shown in FIG. 3. With reference to FIG. 6A, the distance between adjacent two N-type diffusion layers 21 is allowed to be enlarged under a condition that the substrate bias is firmly fixed over the N-well 1. In this case, each power switch cell 20 is not necessary to include an N-well diffusion layer 21. In the example of FIG. 6A, one N-type diffusion layers 21 is arranged for every two power switch cells 20. In the arrangement of FIG. 6A, power switch cells 20 with the N-type diffusion layers 21 and power switch cells 20′ without N-type diffusion layers 21 are arranged in an alternate fashion.

On the other hand, the distance between adjacent two power switch cells 20 is allowed to be enlarged under a condition that the source bias of the P-type MOS transistors 11 is firmly fixed. In this case, as shown in FIG. 6B, the functional cell 100 may further include N-well contact regions 26 (one shown) each including an N-type diffusion layers 27 that function as well contacts to the N-well 1. In the arrangement of FIG. 6B, two N-type diffusion layers used as the well contacts are provided for one power switch cells 20. In this case, the power switch cells 20 with the N-type diffusion layers 21 and the N-well contact regions 26 with the N-type diffusion layers 27 are arranged in an alternate fashion. Such arrangement allows further reducing the circuit size of the functional cell 100, since the cell width of the well contact regions 26 is allowed to be narrower than that of the power switch cells 20.

### Second Embodiment

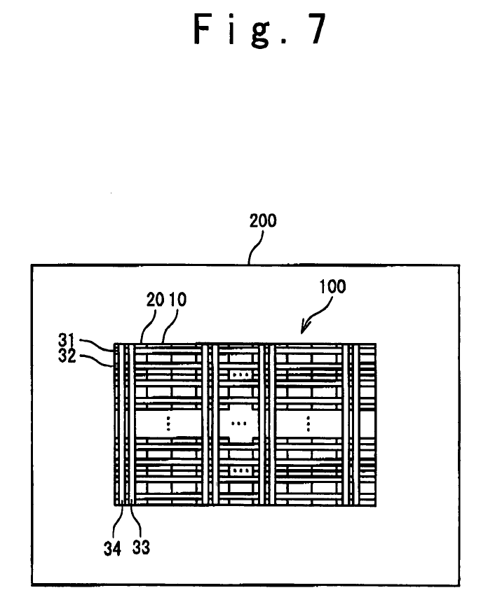

A description is given of an integrated circuit 200 of a second embodiment of the present invention, referring to FIG. 7 to 10. In the second embodiment, different power source voltages are supplied as the substrate and source biases of the power switch cells 20; it should be noted that, in the first embodiment, the power source voltage VDD is commonly supplied as the substrate and source biases.

FIG. 7 is a plain view of the integrated circuit 200 of the second embodiment. In this embodiment, the functional cell 100 is provided with VDD1 power lines 33 and VDD2 power lines 34, instead of the VDD power lines 31. The VDD1 power lines 33 and VDD2 power lines 34 are fed with separately-generated power source voltages; the VDD1 power lines 33 are fed with a power source voltage VDD1 while the VDD2 power lines 34 are fed with a power source voltage VDD2. Other configurations of the functional cell 100 of the second embodiment are the same as those of the functional cell 100 of the first embodiment. In the second embodiment, the power switch cells 20 supplies a virtual power source voltage VSD generated from the power source voltage VDD1 on the VDD1 power lines 33, to the primitive cells 10 through the VSD power lines 31. The primitive cells 10 each include a logic circuit which operates on the virtual power source voltage VSD and the ground voltage GND supplied from the VSD power lines 31 and the ground line 32, respectively. In addition, the power source voltage VDD2 is supplied from the VDD2 power line 34 to the N-well 1 as the substrate bias, through the well contacts 21.

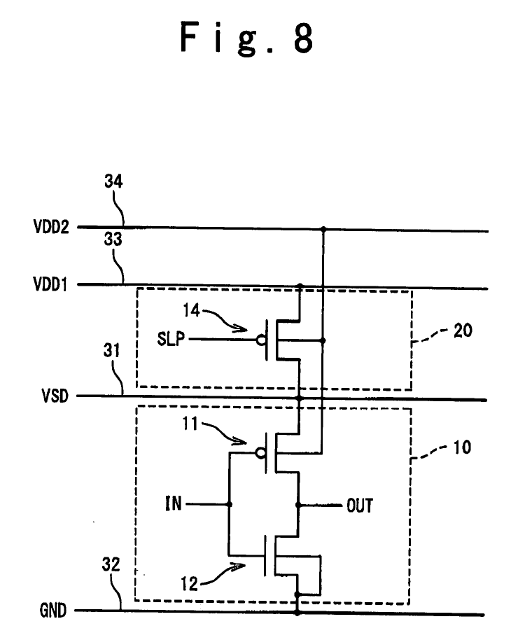

FIG. 8 is a circuit diagram illustrating an exemplary configuration of the primitive cells 10 and the power switch cells 20 in the second embodiment. The primitive cells 10 each include a PMOS transistor 11 having a source connected with the VSD power line 31 and an NMOS transistor 12 having a source connected with the ground line 32. The PMOS and NMOS transistors 11 and 12 are connected each other to function as a CMOS device, outputting an output signal OUT in response to an input signal IN. Although shown as including a CMOS inverter in FIG. 8, the primitive cells 10 may include other kinds of CMOS circuits. The substrate node (or the backgate) of the PMOS transistor 11 is biased with the power source voltage VDD2 received from the VDD2 power line 34, and the substrate node (or the backgate) of the NMOS transistor 12 is biased with the ground voltage GND received from the ground line 32.

The power switch cells 20 each include a PMOS transistor 14 connected between the VDD1 power line 33 and the VSD power line 31. The PMOS transistor 14 supplies the virtual power source voltage VSD, which corresponds to the power source voltage VDD1 received from the VDD1 power line 30, to the VSD power line 31. The PMOS transistor 14 controls the supply of the virtual power source voltage VSD in response to a switch control signal SLP fed to the gate thereof. The power source voltage VDD2 is supplied to the substrate node (or the backgate) of the PMOS transistor 14 from the VDD2 power line 34. Although FIG. 8 shows a configuration in which only one primitive cell 10 is prepared for one power switch cell 20, it would be understood that multiple power switch cells 20 may be connected with multiple primitive cells 10.

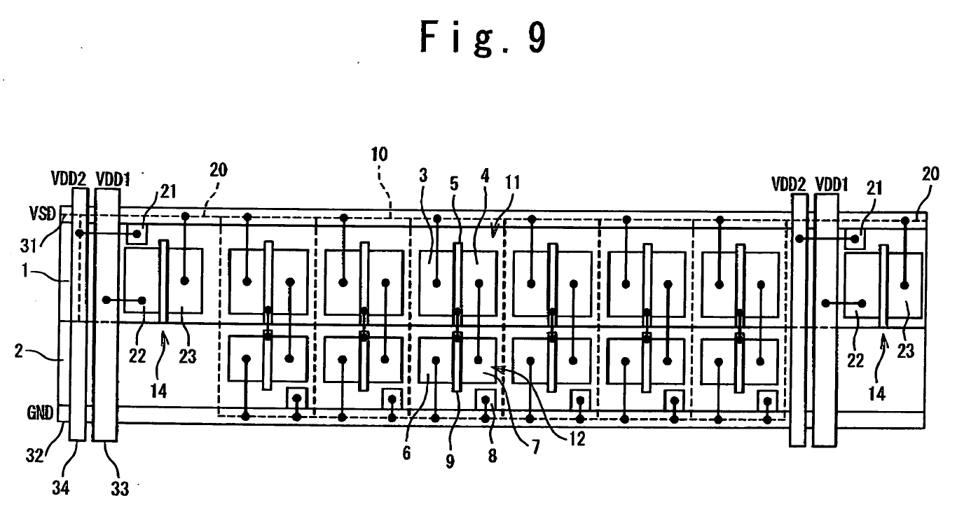

FIG. 9 is a plain view showing an exemplary layout of the functional cell 100 and connections of elements within the functional cell 100. The PMOS transistors 11 of the primitive cells 10 are provided within an N-well 1, while the NMOS transistors 12 are provided within a P-well 2. The PMOS transistors 11 are each composed of P-type diffusion layers 3, 4 and a gate 5, the P-type diffusion layers 3 and 4 being formed within the N-well 1. The NMOS transistors 12 are each composed of N-type diffusion layers 6, 7 and a gate 9, the N-type diffusion layers 6 and 7 being provided within the P-well 2. The PMOS transistors 14 within the power switch cells 20 are also prepared within the N-well 1, commonly with the PMOS transistors 11.

As is the case of the first embodiment, well contacts that supply the substrate bias (or the backgate bias) of the PMOS transistors 11 are provided within the N-well 1 outside the primitive cells 10 in the second embodiment. In this embodiment, the well contacts are formed as N-type diffusion layers 21 within the power switch cells 20. The N-type diffusion layers 21 are connected to the VDD2 power lines 34, and the power source voltage VDD2 is supplied to the respective N-type diffusion layers 21; the power source voltage VDD2 is supplied through the N-type diffusion layers 21 to the N-well 1 as the substrate bias for both of the PMOS transistors 11 and 14.

The substrate bias (or the backgate bias) of the NMOS transistors 12 is supplied to the P-well 2 through P-type diffusion layers 8 provided within the primitive cells 10, the P-type diffusion layers 8 functioning as well contacts. The P-type diffusion layers 8 are connected to the ground line 32. The ground voltage GND is supplied to the P-well 2 as the substrate bias, within each primitive cell 10.

The PMOS transistors 14 within the power switch cells 20 are each provided with P-type diffusion layers 22, 23 and a gate 24. The P-type diffusion layers 22, which function as source regions, are connected with the VDD1 power lines 33 through via-contacts (not shown in FIG. 9), and the power source voltage VDD1 is supplied to the P-type diffusion layers 22. The P-type diffusion layers 23, which function as drain regions, are connected with the VSD power lines 31 through via-contacts (not shown in FIG. 3). The virtual power potential VSD is supplied to the VSD power lines 31 from the P-type diffusion layers 23. It should be noted that the substrate bias fed to the N-well 1 has a bias level different from that of the source bias of the PMOS transistor 14; the level of the substrate bias is identical to the power source voltage VDD2, while the level of the source bias is identical to the power source voltage VDD1. It should be noted that the configuration of the functional cell 100 is schematically illustrated in FIG. 9 for easy understanding. Although the VDD1 power lines 33 are shown in FIG. 9 as being separated from the P-type diffusion layers 22 in the in-plane direction, the P-type diffusion layers 22 may be positioned just under the VDD1 power lines 33 and connected with the VDD1 power line 33 through via-contacts. Correspondingly, although the VDD2 power lines 34 are shown in FIG. 9 as being separated from the N-type diffusion layers 21 in the in-plane direction, the P-type diffusion layers 22 may be positioned just under the VDD2 power lines 34 and connected with the VDD2 power line 34 through via-contacts.

The P-type diffusion layer 3, which function as the source regions of the PMOS transistors 11, are connected to the VSD power lines 31 through via-contacts (not shown in FIG. 9), and the virtual power source voltage VSD is supplied to the P-type diffusion layers 3. The N-type diffusion layers 6, which function as the source regions of the NMOS transistors 12, are connected with the ground lines 32 through via-contacts (not shown in FIG. 9), and the ground voltage GND is supplied to the N-type diffusion layers 6. The gates 5 of the PMOS transistors 11 are connected with the gates 9 of the NMOS transistors 12, respectively, and the P-type diffusion layers 4 (the drain regions) of the PMOS transistors 11 are connected with the N-type diffusion layers 7 (the drain region) of the NMOS transistors 12, respectively.

Similarly to the first embodiment, the VSD power lines 31 and the ground lines 32 are both provided in the first interconnection layer (the lowest interconnection layer), extending in parallel with each other in the horizontal direction. The VDD1 power lines 33 and the VDD2 power lines 34 are, on the other hand, provided in an upper interconnection layer positioned over the first (lowest) interconnection layer; extending along the column of the power switch cells 20 in the vertical direction; such arrangement facilitates providing electrical connections between the VDD1 power lines 33 and the P-type diffusion layers 22, and between the VDD2 power lines 34 and the N-type diffusion layers 21. In the second embodiment, the VDD1 power lines 33 and the VDD2 power lines 34 are not required to be positioned provided in the first (lowest) interconnection layer, since the power source voltage is not supplied to each primitive cell 10, differently from the conventional integrated circuit shown in FIG. 11. Therefore, the integrated circuit of this embodiment does not require providing the separation “a” for separating the VDD power line from the VSD power line, differently from the conventional integrated circuit shown in FIG. 11; the circuit size of the integrated circuit of this embodiment depends on the cell height “e” of the primitive cells 10. Therefore, the layout of the integrated circuit in this embodiment effectively reduces the circuit size in comparison with the conventional technique.

It should be also noted that, the substrate biases of the PMOS transistors 11 and 14 are controllable independently from the source bias of the PMOS transistor 14 in the second embodiment; the levels of the substrate biases of the PMOS transistors 11 and 14 are identical to the level of the power source voltage VDD2, which is generated independently from the power source voltage VDD1. Therefore, the threshold voltages of the PMOS transistors 11 and 14 are independently controllable to desired values by controlling the power source voltages VDD1 and VDD2. This allows flexibly determining the number of the P-type diffusion layers 21 and/or the intervals of adjacent two P-type diffusion layers 21 (that is, the number of the primitive cells 10 arranged between adjacent two P-type diffusion layers 21).

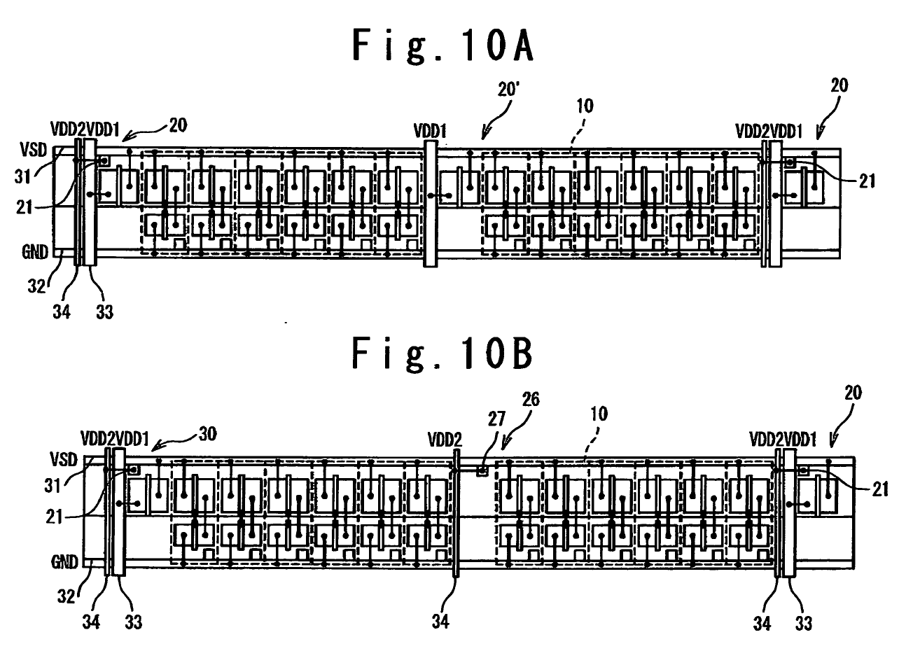

FIGS. 10A and 10B are other exemplary arrangements of the power switch cells 20 and the N-type diffusion layers 21, which are the well contacts to the N-well 1. The numbers of N-type diffusion layers 21 and the power switch cell 20 may be arbitrary modified depending on the drive capacities of the PMOS transistors 11 and 14; the N-type diffusion layers 21 and the power switch cell 20 may not be in one-to-one correspondence to each other as shown in FIG. 9. In the example of FIG. 10A, one N-type diffusion layers 21 is arranged for every two power switch cells 20. In the arrangement of FIG. 10A, power switch cells 20 with the N-type diffusion layers 21 and power switch cells 20′ without N-type diffusion layers 21 are arranged in an alternate fashion. It should be noted that the VDD2 power lines 34 are provided over only the power switch cells 20; the VDD2 power lines 34 are not provided over the power switch cells 20′. Therefore, the arrangement of FIG. 10A allows reducing the total length of the power source lines, effectively reducing the circuit size.

On the other hand, the distance between adjacent two power switch cells 20 is allowed to be enlarged under a condition that the source bias of the P-type MOS transistors 11 is firmly fixed. In the arrangement of FIG. 10B, for example, two N-type diffusion layers used as the well contacts are provided for one power switch cells 20. In this case, the power switch cells 20 with the N-type diffusion layers 21 and the N-well contact regions 26 with the N-type diffusion layers 27 are arranged in an alternate fashion. Such arrangement allows further reducing the circuit size of the functional cell 100, since the cell width of the well contact regions 26 is allowed to be narrower than that of the power switch cells 20. Additionally, only the VDD2 power lines 34 are required to be provided over the well contact regions 26 in the arrangement of FIG. 10B. Therefore, the arrangement of FIG. 10B effectively reduces the total length of the power source lines, effectively reducing the circuit size.

As described above, the present invention provides a layout for effectively reducing the circuit size of functional cells adapted to control the power supply for reducing the leak current. It should be noted that the layout of the above mentioned functional cell 100 may be designed by executing a layout program recorded on a computer-readable recording medium.

It is apparent that the present invention is not limited to the above embodiments, but may be modified and changed without departing from the scope of the invention.

What is claimed is:

1. An integrated circuit comprising:
a first power line;
a plurality of additional power lines intersecting with said first power line;
a plurality of power switch transistors each having a drain connected with said first power line and a source connected with one of said additional power lines;
a well provided to extend along said first power line; and
a plurality of primitive cells each including a first transistor prepared within said well, said first transistor having a source connected with said first power line,
wherein said plurality of additional power lines includes first and second additional power lines,
wherein said plurality of primitive cells are provided between said first and second additional power lines along said first power line;
a bias voltage is fed to said well through both of first and second well contacts, said first well contact providing a connection between said first additional power line and said well, and said second well contact providing a connection between said second additional power line and said well.

2. The integrated circuit according to claim 1, wherein at least one of said plurality of power switch transistors has a source connected with said first additional power line, and a drain connected with said first power line.

3. The integrated circuit according to claim 1, wherein said plurality of additional power lines further includes a third additional power line,
wherein at least one of said plurality of power switch transistors has a source connected with said third additional power line, and a drain connected with said first power line.

4. The integrated circuit according to claim 2, wherein at least one of remaining one(s) of said plurality of power switch transistors has a source connected with said second additional power line, and a drain connected with said first power line.

5. The integrated circuit according to claim 1, wherein said plurality of power switch transistors are formed within said well.

6. An integrated circuit comprising:
a plurality of first direction power lines;
a plurality of second direction power lines intersecting with said plurality of first direction power lines;
a plurality of power switch transistors each having a drain connected with one of said plurality of first direction power lines and a source connected with one of said plurality of second direction power lines;
a plurality of wells each provided to extend along one of said plurality of first direction power lines;
a plurality of primitive cells each including a first transistor prepared within one of said plurality of wells, said first transistor having a source connected with corresponding one of said plurality of first direction power lines; and
a plurality of well contacts each providing a connection between one of said plurality of wells and one of said plurality of second direction power lines.

7. The integrated circuit according to claim 6, wherein said plurality of second direction power lines are each connected with said plurality of wells each via corresponding one of said plurality of well contacts, and are each connected with said plurality of first direction power lines each via corresponding one of said plurality of power switch transistors.

8. The integrated circuit according to claim 6, wherein said plurality of second direction power lines comprise first type second direction power lines, and second type second direction power lines,
wherein said first type second direction power lines are each connected to said plurality of wells each via corresponding one of said plurality of well contacts, and are each connected to said plurality of first direction power lines each via corresponding one of power switch transistors,
wherein said second type second direction power lines are each connected to said plurality of first direction power lines each via corresponding one of power switch transistors.

9. The integrated circuit according to claim 6, wherein said plurality of second direction power lines comprise first type second direction power lines, and second type second direction power lines,
wherein said first type second direction power lines are each connected to said plurality of wells each via corresponding one of said plurality of well contacts, and are each connected to said plurality of first direction power lines each via corresponding one of power switch transistors,
wherein said second type second direction power lines are each connected to said plurality of wells each via corresponding one of said plurality of well contacts.

10. The integrated circuit according to claim 6, wherein said plurality of second direction power lines comprise first type second direction power lines, and second type second direction power lines,
wherein said first second direction power lines are each connected to said plurality of wells each via corresponding one of said plurality of well contacts,
wherein said second type second direction power lines are each connected to said plurality of first direction power lines each via corresponding one of power switch transistors.

11. The integrated circuit according to claim 10, wherein a distance between said first type second direction power lines is substantially equal to a distance between said second type second direction power lines.

12. The integrated circuit according to claim 10, wherein a distance between said first type second direction power lines is substantially an integral multiple of a distance between said second type second direction power lines.

13. The integrated circuit according to claim 10, wherein a distance between said second type second direction power lines is substantially an integral multiple of a distance between said first type second direction power lines.
